(19) United States
(12) Patent Application Publication
(10) Pub. No.: US 2022/0269652 A1
(43) Pub. Date: Aug. 25, 2022

(54) COMPUTATION APPARATUS AND COMPRESSION METHOD

(71) Applicant: Hitachi, Ltd., Tokyo (JP)

(72) Inventors: Akifumi Suzuki, Tokyo (JP); Hiroaki Akutsu, Tokyo (JP)

(73) Assignee: Hitachi, Ltd., Tokyo (JP)

(21) Appl. No.: 17/673,042

(22) Filed: Feb. 16, 2022

(30) Foreign Application Priority Data
Feb. 22, 2021 (JP) 2021-026108

(51) Int. Cl. G06F 16/174; G06N 3/08

(52) U.S. Cl. CPC G06F 16/1744; G06N 3/08

(57) ABSTRACT

The computation load of computation using a neural network can be lowered. A computation apparatus has a prediction device, an encoder, and a decoder, and encodes and decodes data by using a probability density distribution. Of a learning process and a compression process, at least the compression process can be executed. By performing learning by using a neural network created by the learning process, a probability distribution table that causes a parameter and a symbol value probability distribution to correspond to each other can be used. In the compression process, the prediction device calculates the parameter from input data, and the encoder compresses the input data by using the symbol value probability distribution on the basis of the calculated parameter and the probability distribution table.

### BACKGROUND

The present invention relates to a computation apparatus and a compression method.

Techniques that make computation more efficient by using a neural network have been known, as described in, for example, Non-Patent Literature 1 (Johannes Balle, and two others, “End-to-end Optimized Image Compression”, [online], Mar. 3, 2017, arXiv, [searched on Aug. 4, 2020], the Internet, <URL: https://arxiv.org/abs/1611.01704>). Like these, it has been known that a learning type compression and decompression device (hereinafter, called a “learning type compression device”) built by the neural network enables conversion to higher image quality at the same amount of data or equivalent image quality at a smaller amount of data, as compared with a compression technique, such as JPEG.

### SUMMARY

The learning type compression device described above acquires a parameter suitable for a data compression process through learning. As this neural network learning method, an error back propagation method has been known, and this error back propagation method is required to describe a process to be learned by a differentiable function. More specifically, there is a process by which in the compression process, an image is converted to a multidimensional tensor form called a feature amount map that enables data reduction, and the appearance probability of an element value (hereinafter, called a “symbol value”) in the feature amount map is then predicted. The symbol value takes, for example, only an integer value in a particular range (example: −100 to +100), and the appearance probability of each integer value taken by the symbol value at each of all the positions in the feature amount map is outputted as a prediction value. When among the predicted appearance probabilities, the probability of the actual symbol value is sufficiently high, encoding that reduces the amount of data by the entropy encoding of a range coder or the like is enabled.

As a specific method of this probability prediction, the learning type compression device uses a prediction device built by the neural network. More specifically, this prediction device outputs plural parameters of a differentiable probability density function (for example, a mean and a standard deviation of a Gaussian distribution), and each probability density function is created at each position in the feature amount map to calculate the appearance probability of each integer value in the symbol value range. Since the probability density function is differentiable, this configuration can learn the prediction device by the error back propagation method so as to create the parameter in which the probability of the symbol value to be encoded becomes maximum.

In the learning described above, the process that combines the prediction device and the probability density function can predict the appearance probability of the symbol value, but is a process with a high calculation load using an exponential function or the like, as the probability density function of the Gaussian distribution or the like, and requires much time and calculation resources for calculation. Consequently, the compression processing time increases, or the processing resources performing the compression process, for example, the central processing unit and the GPU (Graphic Processing Unit) are required to be more expensive. In this way, the computation using the neural network has a problem that the computation load is large.

According to a first aspect of the present invention, a computation apparatus has a prediction device, an encoder, and a decoder, and encodes and decodes data by using a probability density distribution. Of a learning process and a compression process, at least the compression process can be executed. By performing learning by using a neural network created by the learning process, a probability distribution table that causes a parameter and a symbol value probability distribution to correspond to each other can be used. In the compression process, the prediction device calculates the parameter from input data, and the encoder compresses the input data by using the symbol value probability distribution on the basis of the calculated parameter and the probability distribution table.

According to a second aspect of the present invention, a compression method is executed by a computation apparatus that has a prediction device, an encoder, and a decoder and encodes and decodes data by using a probability density distribution. The computation apparatus can execute, of a learning process and a compression process, at least the compression process. By performing learning by using a neural network created by the learning process, a probability distribution table that causes a parameter and a symbol value probability distribution to correspond to each other can be used.

The compression process includes calculating, by the prediction device, the parameter from input data, and compressing, by the encoder, the input data by using the symbol value probability distribution on the basis of the calculated parameter and the probability distribution table.

According to the present invention, the computation load of the computation using the neural network can be lowered.

### BRIEF DESCRIPTION OF THE DRAWINGS

FIG. 1 is a block diagram of a sensor system;

FIG. 2 is a function block diagram of a computation apparatus according to a first embodiment;

FIG. 3 is a diagram illustrating an example of a setting table;

FIG. 4 is a diagram illustrating an example of an index correspondence table;

FIG. 5 is a diagram illustrating an example of a distribution table;

FIG. 6 is a flow diagram illustrating a compression process;

FIG. 7 is a diagram illustrating an example of a compression file;

FIG. 8 is a flow diagram illustrating a decompression process;

FIG. 9 is a diagram illustrating an example of a user interface screen;

FIG. 10 is a function block diagram of a computation apparatus according to modification example 9;

FIG. 11 is a function block diagram of a computation apparatus according to a second embodiment; and

FIG. 12 is a flowchart illustrating an index decision process according to the second embodiment.

### DETAILED DESCRIPTION

### First Embodiment

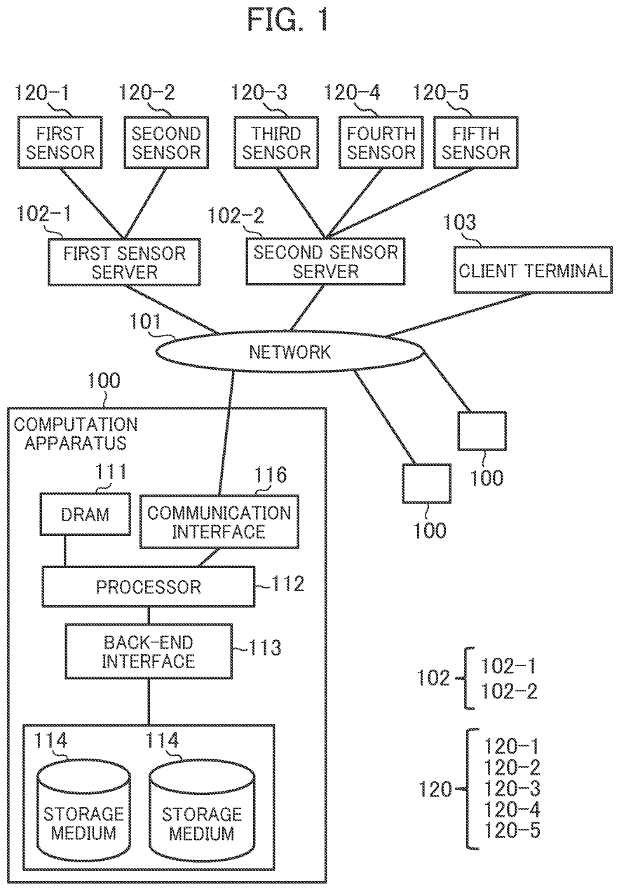

Hereinafter, a first embodiment of a computation apparatus according to the present invention will be described with reference to FIGS. 1 to 9.

FIG. 1 is a block diagram of a sensor system including the computation apparatus. The sensor system includes plural sensors 120, plural sensor servers 102, a client terminal 103, and plural computation apparatuses 100. One or more sensors 120 are connected to each of the sensor servers 102. The sensors 120 include a first sensor 120-1, a second sensor 120-2, a third sensor 120-3, a fourth sensor 120-4, and a fifth sensor 120-5.

Each of the sensors 120 is, for example, a camera, a video camera, a laser distance meter, a speed meter, a temperature meter, a voltage meter, or the like. The sensor servers 102 include a first sensor server 102-1 and a second sensor server 102-2. The respective sensor servers 102 have connection interfaces with the sensors 120, and connection interfaces with a network 101. Each of the interfaces needs only to enable communication, and can be used by wire connection and wireless connection alike.

The network 101 may be a wide area network, such as the Internet, or may be a local area network. The plural sensors 120 are not necessarily required to be included in the sensor system, and only one sensor 120 may be included in the sensor system. The plural sensor servers 102 are not necessarily required to be included in the sensor system, and only one sensor server 102 may be included in the sensor system. The respective sensors 120 may be directly connected to the network 101 not via the sensor servers 102. In FIG. 1, three computation apparatuses 100 are included in the sensor system, but at least one computation apparatus 100 needs only to be included in the sensor system.

Each of the computation apparatuses 100 includes a DRAM 111 that is a primary storage region, a processor 112 that performs various processes according to software, a back-end interface 113 connected to a storage medium 114, the storage medium 114 that is a secondary storage region, and a communication interface 116 connected to the network 101. The DRAM 111 is connected to the processor 112 by connection that can be accessed from the processor 112 in a short time. The DRAM 111 stores a program and data to be processed that are processed by the processor 112.

The processor 112 operates according to the program to process the target data. The processor 112 has plural processor cores therein, each of the processor cores independently or cooperatively processing the program. The processor 112 has, in its interior, a DRAM controller to acquire the data from the DRAM 111 according to a request from the processor or store the data in the DRAM 111. The processor 112 has an external I/O interface to be connected to the back-end interface 113. The processor 112 notifies an instruction to the storage medium 114 that is a secondary storage device via the back-end interface 113. The processor 112 performs various processes described later associated with the compression and decompression of sensor data.

The processor 112, not only performs the data compression and decompression processes, but also operates software associated with a storage, such as an SDS (Software Defined Storage) or a database. With this, after compressing the received sensor data, the processor 112 distributes the compressed data to a node group configured of the plural computation apparatuses 100, thereby storing the data. At this time, the processor 112 records the data in the storage medium 114 according to the control of the SDS or the database.

The back-end interface 113 is a communication interface corresponding to a communication standard, such as SATA (Serial ATA) or SAS (Serial Attached SCSI). At the time of writing, on the basis of an instruction from the processor 112, the back-end interface 113 acquires data to be written from the DRAM 111 to transfer the data to the storage medium 114. Also, at the time of reading, on the basis of an instruction from the processor 112, the back-end interface 113 acquires data to be read from the storage medium 114 to transfer the data to the DRAM 111.

Note that in this embodiment, the back-end interface 113 and the storage medium 114 are independent, but the back-end interface 113 and the storage medium 114 may be integrated. Further, each of the computation apparatuses 100 may be equipped with an interface that directly communicates with the processor 112, for example, an NVMe (Non-Volatile Memory Host Controller Interface) in the storage medium 114 without including the back-end interface 113.

The storage medium 114 is the secondary storage device that stores data to be analyzed. In this embodiment, the storage medium 114 receives data to be written transmitted from the back-end interface 113 controlled by the processor 112, and permanently stores the data. The communication interface 116 is an interface for communicating with other computation apparatuses 100, the sensor servers 102, and the client terminal 103. In the example in FIG. 1, the computation apparatus 100 is connected to other apparatuses via the network 101, but may be directly connected to other apparatuses not via the network 101.

The sensor servers 102 manage the plural sensors 120, and transfer data acquired by the respective sensors 120 (hereinafter, called “sensor data”) to the computation apparatus 100 via the network 101. The computation apparatus 100 that has received the sensor data from the sensor servers 102 compresses the sensor data by a compression process described later, and stores the data in the storage medium 114.

The client terminal 103 is a terminal used in using, by the user, the sensor data stored in the computation apparatus 100, and requests the sensor data to the computation apparatus 100. The computation apparatus 100 that has received the request from the client terminal 103 decompresses the sensor data by a decompression process described later, and transfers the data to the client terminal 103.

Function Configuration

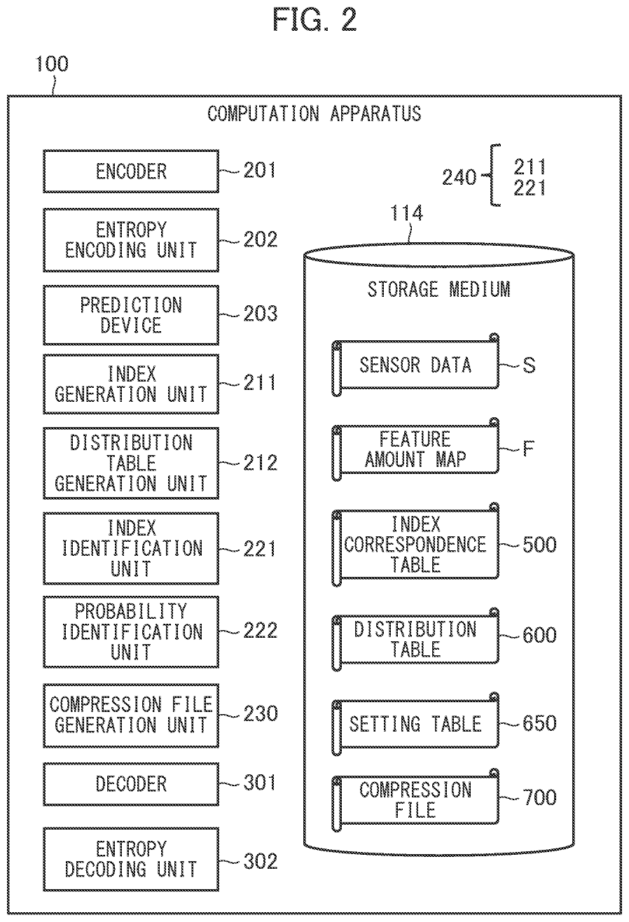

FIG. 2 is a function block diagram of the computation apparatus 100. The computation apparatus 100 includes, as the functions thereof, an encoder 201, an entropy encoding unit 202, a prediction device 203, an index generation unit 211, a distribution table generation unit 212, an index identification unit 221, a probability identification unit 222, a compression file generation unit 230, a decoder 301, and an entropy decoding unit 302. Also, the storage medium 114 of the computation apparatus 100 can store sensor data S, a feature amount map F, an index correspondence table 500, a distribution table 600, a setting table 650, and a compression file 700. However, all the data described above stored in the storage medium 114 are not required to be stored in the storage medium 114 at the same time. Note that hereinafter, the index generation unit 211 and the index identification unit 221 are sometimes collectively called an “index generation unit” 240. Also, the distribution table generation unit 212 is sometimes called a “correspondence information generation unit”.

The sensor data S is data acquired by each of the sensors 120, and the computation apparatus 100 acquires the sensor data S via each of the sensor servers 102. The compression file 700 is acquired by subjecting the sensor data S to the compression process, and the sensor data S is acquired by subjecting the compression file 700 to the decompression process. The index correspondence table 500 is created by the index generation unit 211. The index generation unit 211 refers to the setting table 650 in the creation of the index correspondence table 500. The index correspondence table 500 is a table that represents the correspondence between the index value and the parameter outputted by the prediction device 203. The detail of the information stored in the index correspondence table 500 will be described later. The feature amount map F is the sensor data S converted by the encoder 201. Hereinafter, an element in the feature amount map F is called a “symbol”.

The distribution table 600 is created by the distribution table generation unit 212. The distribution table generation unit 212 refers to the setting table 650 in the creation of the distribution table 600. The distribution table 600 is a table that represents the correspondence between the index value and the cumulative frequency. The setting table 650 stores the previously determined cumulative frequency and the parameter related to feature amount extraction, in other words, the information that defines a predetermined range described later referred in index decision. However, as described later, the value of the parameter stored in the setting table 650 may be updated by the operation of the user.

The operation outline of the respective configurations included in the computation apparatus 100 is as follows. The encoder 201 reads the sensor data S, and outputs the feature amount map F. The prediction device 203 reads the feature amount map F, and outputs two parameters, that is, a parameter A and a parameter B. The parameter A and the parameter B will be described later in detail. The index identification unit 221 refers to the index correspondence table 500, and identifies the index corresponding to the combination of the two parameters outputted by the prediction device 203. The probability identification unit 222 refers to the distribution table 600, and outputs, to the entropy encoding unit 202, the cumulative frequency corresponding to the index value outputted by the index identification unit 221.

The entropy encoding unit 202 reads the feature amount map F, and creates one portion of the compression file 700. At this time, the entropy encoding unit 202 achieves the efficient compression of the feature amount map F by referring to the cumulative frequency outputted by the probability identification unit 222. Thus, the entropy encoding unit 202 can also be called a “compression unit”. Another portion of the compression file 700 is generated by the compression file generation unit 230.

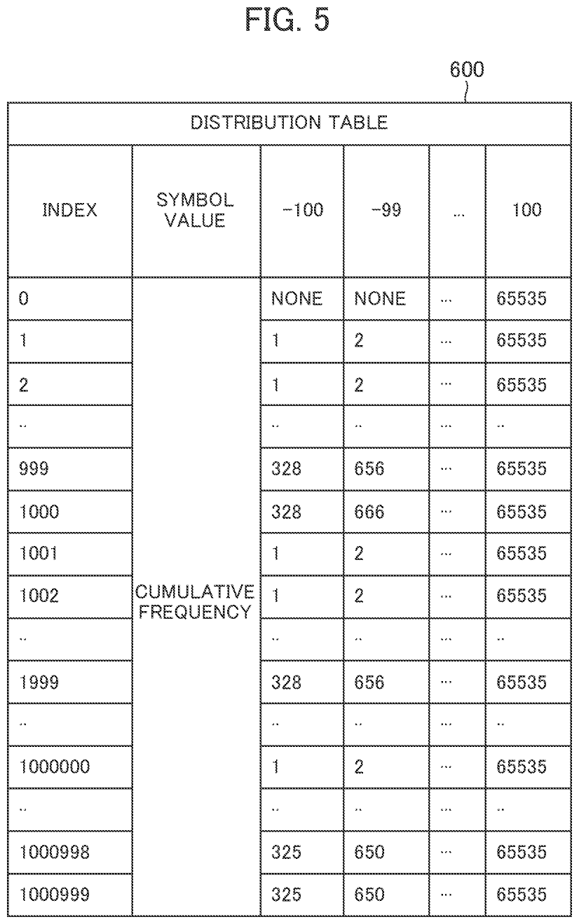

The entropy encoding unit 202 efficiently encodes the data by using the value in the distribution table 600 described later. The distribution table 600 describes the cumulative frequency of each of the respective symbol values of −100 to 100, and the number of types of the symbol values is 201, so that when the occurrence probabilities of the respective symbol values are uniform, each symbol has a probability of 1/201. Here, when the probability of the symbol value to be encoded, in the distribution table acquired from the result of the prediction device is larger than 1/201, for example, 1/10 (in the example in the distribution table in FIG. 5, when about 6554 cumulative frequencies increase with respect to the cumulative frequencies of the previous symbol values in the table), the data can be recorded by being encoded to a smaller amount of data. In this case, unless the same value as the cumulative frequency used for encoding is used in decoding, the data cannot be precisely decoded.

The index generation unit 211 refers to the setting table 650, and generates the index correspondence table 500. The distribution table generation unit 212 refers to the setting table 650, and generates the distribution table 600. Note that the index generation unit 211 and the distribution table generation unit 212 sometimes operate by referring to the information corresponding to the setting table 650 included in the compression file 700 instead of the setting table 650. The decoder 301 reads the feature amount map F, and outputs the sensor data S. The entropy decoding unit 302 creates the compression file 700 by using the feature amount map F and the cumulative frequency outputted by the probability identification unit 222.

Setting Table

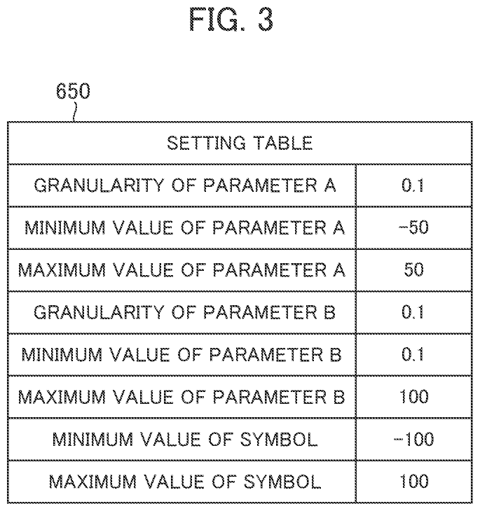

FIG. 3 is a diagram illustrating an example of the setting table 650. The setting table 650 includes the granularity of the parameter A, the minimum value of the parameter A, the maximum value of the parameter A, the granularity of the parameter B, the minimum value of the parameter B, the maximum value of the parameter B, the minimum value of the symbol, and the maximum value of the symbol. These values need only to be real numbers, and are any value.

The index generation unit 211 reads, among the information stored in the setting table 650, the granularity of the parameter A, the minimum value of the parameter A, the maximum value of the parameter A, the granularity of the parameter B, the minimum value of the parameter B, and the maximum value of the parameter B, and reflects the values to the operation. Thus, the granularity of the parameter A, the minimum value of the parameter A, the maximum value of the parameter A, the granularity of the parameter B, the minimum value of the parameter B, and the maximum value of the parameter B can also be called “index parameter information” that identifies the operation parameter of the index generation unit 211.

Since the distribution table generation unit 212 reads all the information stored in the setting table 650, and reflects the information to the operation, it can also be said that the information in the setting table 650 is reflected to the distribution table 600 generated by the distribution table generation unit 212. Thus, the granularity of the parameter A, the minimum value of the parameter A, the maximum value of the parameter A, the granularity of the parameter B, the minimum value of the parameter B, the maximum value of the parameter B, the minimum value of the symbol, and the maximum value of the symbol can also be called “probability identification information” that identifies the distribution table 600.

Index Correspondence Table

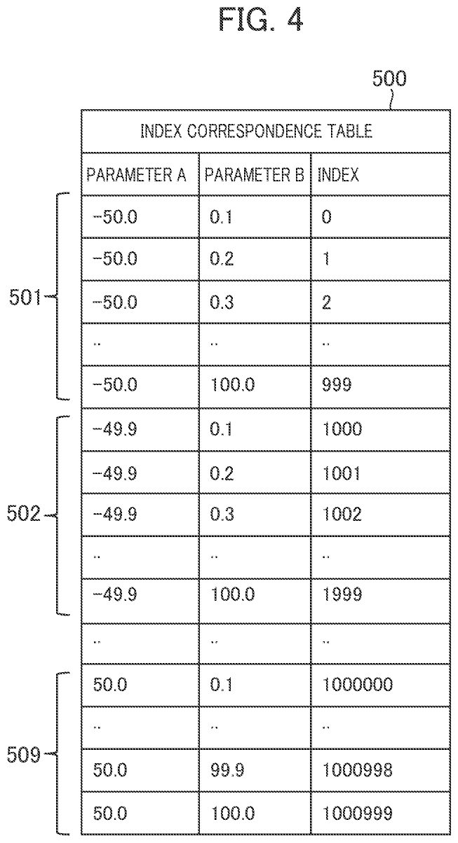

In the conventional art, the parameter A and the parameter B that are real numbers outputted by the prediction device are used to create each probability of a probability density distribution by computation, and on the basis of each probability, the cumulative frequency is created. However, in this example, an integer index is created by the parameter A and the parameter B, and by using the integer index, the value of the cumulative frequency that has already been created is acquired. A method for creating the integer index by the parameter A and the parameter B may use computation, but in this example, the integer index is acquired from the index correspondence table 500 illustrated in FIG. 4.

FIG. 4 is a diagram illustrating an example of the index correspondence table 500, and corresponds to the values in the setting table 650 illustrated in FIG. 3. Note that the reference numerals 501 to 509 in FIG. 4 will be referred in the following description. The example illustrated in FIG. 4 represents that when the parameter A is “−50.0” and the parameter B is “0.2”, the index value is “1”. For example, the index generation unit 211 creates the index correspondence table 500 that is a list of the indexes corresponding to the parameter A and the parameter B that are the outputs of the prediction device 203 as follows.

First, the index generation unit 211 causes the combination of “−50” that is the minimum value of the parameter A and “0.1” that is the minimum value of the parameter B to correspond to the first index, that is, the index value “0”. Then, the index generation unit 211 increases the parameter B to “100.0” that is the maximum value of the parameter B by “0.1” that is the granularity of the parameter B while fixing the parameter A to the minimum value. At this time, the index generation unit 211 sets the index value increased by “1” for each combination of the parameter B changed and the minimum value of the parameter A. When the parameter B is increased to “100.0” that is the maximum value of the parameter B, the index value increases to “999”, and the range of the reference numeral 501 in FIG. 4 is completed.

Next, the index generation unit 211 increases the value of the parameter A from the minimum value “−50.0” by “0.1” that is the value of the granularity of the parameter A to update the value of the parameter A to “−49.9”. Then, the index generation unit 211 returns the parameter B to the minimum value “0.1”, and causes this combination to correspond to the next index value “1000”. Then, like the range of the reference numeral 501, the index generation unit 211 increases the parameter B to “100.0” that is the maximum value of the parameter B by “0.1” that is the granularity of the parameter B while fixing the value of the parameter A, and increases the index value to “1999”. By this process, the range of the reference numeral 502 in FIG. 4 is completed.

Thereafter, likewise, the index generation unit 211 increases the value of the parameter A by “0.1” that is the granularity of the parameter A, and repeats the same process as the range of the reference numeral 501 and the range of the reference numeral 502. Then, the index generation unit 211 increases the value of the parameter A to “50.0” that is the maximum value of the parameter A, also increases the value of the parameter B to “100.0” that is the maximum value of the parameter B, and causes the maximum values to correspond to the last index value “1000999” to complete the range of the reference numeral 509. By the above process, the index correspondence table 500 is completed.

Distribution Table

As described above, in the conventional art, the cumulative frequency used by the entropy encoding unit 202 is calculated by computation by using the parameter A and the parameter B that are real numbers. However, in this example, the table of the cumulative frequency that can be referred by using the index (distribution table) is previously created, and the cumulative frequency is acquired without computation. By this, as compared with the case where the cumulative frequency is created by computation by using the parameter A and the parameter B that are real numbers, the compression rate is lowered (when the parameter A and the parameter B described above are sufficiently small, the compression rate is lowered to the level that can be ignored.), but compression is enabled without the probability density function computation process that has a high load.

FIG. 5 is a diagram illustrating an example of the distribution table 600, and corresponds to the values in the setting table 650 illustrated in FIG. 3. In FIG. 5, as illustrated by the left end column, the index value monotonously increases from up toward down. The maximum value of the index is “1000999” that is the same as the index correspondence table 500 in FIG. 4 also corresponding to the value in the setting table 650 illustrated in FIG. 3. “−100” to “100” described in the upper portion of FIG. 5 are the symbol values, and the minimum value and the maximum value correspond to the description of the setting table 650.

The distribution table generation unit 212 refers to the setting table 650, acquires the granularity, the minimum value, and the maximum value of the parameter A, and the granularity, the minimum value, and the maximum value of the parameter B, performs calculation for each of all the combinations of the two parameters by using the probability density function, and calculates the cumulative frequency of the probability value. In this calculation, the probability value is multiplied by the resolution of the cumulative frequency included in the setting table 650. In the example illustrated in FIG. 5, the resolution is 65535, and the cumulative frequency of 100 that is the maximum value in the symbol value range is 65535.

The distribution table 600 is a table that stores the cumulative frequency value corresponding to each of all the symbol values for each index. The distribution table 600 is generated by the distribution table generation unit 212 by referring to the setting table 650. Note that the computation apparatus 100 is not necessarily required to have the distribution table generation unit 212, and the distribution table 600 may be previously created by other than the computation apparatus 100. Also, plural distribution tables 600 may be previously created outside the computation apparatus 100 by assuming various values set to the setting table 650, and the appropriate distribution table 600 may be read according to the value in the setting table 650.

Compression Process

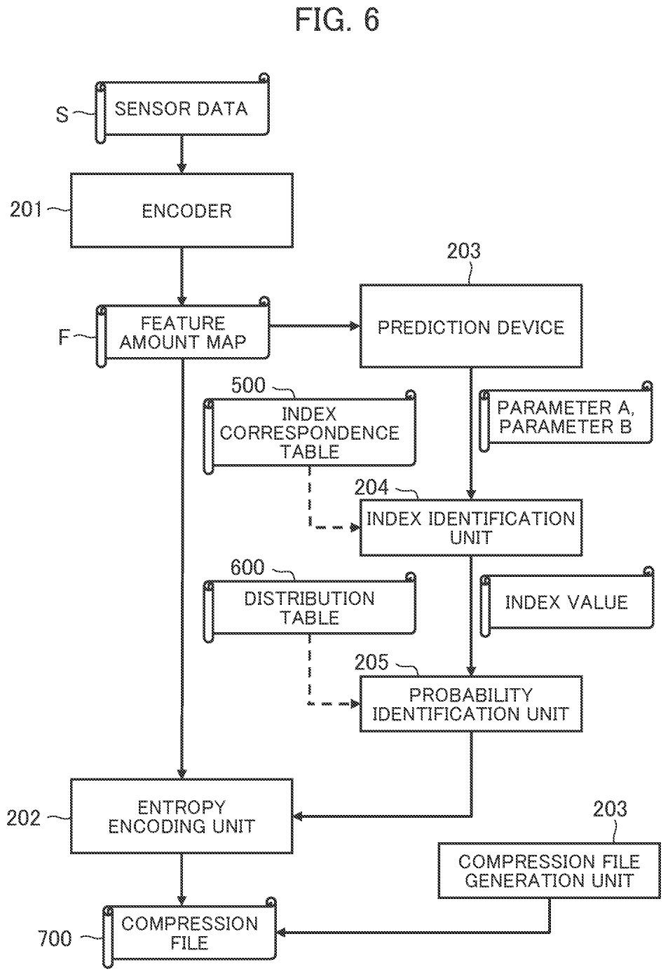

FIG. 6 is a flow diagram illustrating the compression process by the computation apparatus 100. Hereinafter, the compression process will be described mainly by using the sensor data S as a still image. However, the sensor data S that can be processed by the computation apparatus 100 is not limited to the still image. Before the compression process is started, the index correspondence table 500 and the distribution table 600 are previously created. The compression process is started by inputting the sensor data S to the encoder 201.

The encoder 201 converts the sensor data S to the feature amount map F. The encoder 201 reduces the information considered to have a low importance degree while leaving the feature of the sensor data S inputted. For example, when the inputted data is an image, the information that is unlikely to be perceived by a human, for example, the fine change in color or the like, is deleted to reduce the amount of data. Note that the encoder 201 may cause the number of dimensions of the feature amount map F to be different from the number of dimensions of the sensor data S. For example, the encoder 201 converts the sensor data S having a three-dimensional tensor size “3, 512, 512” to the feature amount map F having a three-dimensional tensor size “256, 64, 64”.

Most of the learning type compression devices can learn almost all of the compression process including a prediction process described later by using the neural network for the encoder and the decoder. It has been known that the compression process by the learning type compression device can reduce the amount of data without affecting the image quality that can be perceived by a human, as compared with the non-learning type process that is explicitly designed. In this embodiment, the encoder 201 is built by the neural network, but the encoder 201 is not necessarily required to be built by the neural network. That is, the encoder 201 may perform the explicitly designed process, such as DCT conversion or data decimation used for JPEG and the like.

The feature amount map F is generated by the encoder 201. The feature amount map F typically has a tensor having the same number of dimensions as the sensor data S that is input data. For example, a color image has a three-dimensional tensor of “color, verticality, horizontality”, and when the sensor data S is the color image, the feature amount map F also has a three-dimensional tensor. The magnitude of each dimension of the feature amount map F is often different from that of the sensor data S. For example, the tensor of the color image in which each of the verticality and the horizontality has 512 pixels is “3, 512, 512”, but the feature amount map F can be converted like “256, 64, 64”. Note that the dimension and shape of the feature amount map F are not particularly limited, and the sensor data S may be converted into any shape.

In the feature amount map F, the number of elements can be smaller or larger than the original image, or can be the same as the original image. For example, when the encoder 201 converts the sensor data S having a three-dimensional tensor size “3, 512, 512” to the feature amount map F having a three-dimensional tensor size “256, 64, 64”, the number of elements increases from 3*512*512=786432 to 256*64*64=1048576.

Also, the values of the respective elements in the feature amount map F outputted by the encoder 201 are in an integer form, and hereinafter, one of the elements is denoted as a symbol. The encoder 201 limits the symbol value range, and for simplification, the following description will be made on the assumption that the user limits the symbols to 201 types of integers in the value range of −100 to 100. By limiting the symbol value range, the value of −101 or less is substituted by −100, and the value of 101 or more is substituted by 100. Note that in this example, this value range may be changed by the user by a user interface described later.

The entropy encoding unit 202 performs entropy encoding to reduce the amount of data of the feature amount map F. Various entropy encoding techniques have been known, but in this embodiment, a range coder is used. The range coder performs encoding that reduces the amount of data by using the deviation of the occurrence probability of each symbol value. When the appearance probabilities of 201 types of integers are uniform, each value occurs at 1.0+201=0.495%. However, when the appearance probability is deviated and the appearance probability of the symbol value to be encoded is 0.495% or more, encoding can be performed to a smaller amount of data.

The range coder performs encoding by using the cumulative frequency table, not the appearance probability itself. The cumulative frequency will be described by taking the case where the symbol value range takes five values of −2 to 2 as an example. The appearance probabilities of the respective values of “−2”, “−1”, “0”, “1”, and “2” are “1%, 9%, 20%, 50%, and 20%”, and when the total value of the cumulative frequencies is substituted by 100, the cumulative frequency distribution becomes “1, 9, 20, 50, 20”. When this is assumed to have the cumulative frequencies sequentially from “−2” to “2” that are the symbol values, this becomes “1, 10, 30, 80, 100”. The range coder uses this cumulative frequency table to perform data encoding.

As described above, in the range coder, the amount of data after encoding is changed according to the value appearance probability, strictly, the cumulative frequency table created by this appearance probability. Thus, in the compression process, the capability to predict the appearance probability is the important element of the capability to reduce the amount of data. The computation apparatus 100 predicts this appearance probability by using the prediction device 203 configured of the neural network.

The prediction device 203 is configured to include the neural network that receives, as an input, the feature amount map F, and acquires the capability to predict each appearance probability at each symbol position in the feature amount map F by the known learning process.

This learning process will be described more specifically. When given, as an input, each symbol that configures the feature amount map F, the prediction device 203 outputs the parameters of the probability density distribution according to each symbol (The parameters are outputted for each symbol, and the probability density distribution inherent to each symbol is created.). In this example, the parameters are a mean and a standard deviation that are the parameters of a Gaussian distribution. At this time, the probability of the symbol value of the Gaussian distribution created by the mean and the standard deviation can be calculated. The learning changes the coupling coefficient of the neural network that configures the prediction device so as to have the mean and the standard deviation so that this probability is as large as possible. This change can be learned by the typical error back propagation method since the calculation of the Gaussian distribution can be differentiated. For example, when at the time of inputting a value of 3 as the symbol value to the prediction device, the values, such as the mean of 1.2 and the standard deviation of 2.5, are outputted, there is a possibility that the neural network is corrected so that by the learning, the mean that is the output of the prediction device is brought closer to 3.0 and the standard deviation becomes the value close to 0.0.

However, even in the case where the probability of the symbol can be increased by brining the mean closer to 3 and brining the standard deviation closer to 0, when the probabilities of other symbols inputted to the prediction device are lowered and the average probability of the entire symbol group becomes small, the learning can cause the mean value to be further away from 3 with respect to 1.2 or can also cause the standard deviation to become larger than 2.5, and in this case, there is also a possibility that the probability of 3 of the Gaussian distribution created by the output of the prediction device becomes lower than before the learning. In this way, in the learning, the symbol group in the feature amount map F inputted to the prediction device is inputted, and the neural network that configures the prediction device is corrected so that the average value of the probabilities of the respective symbols of the Gaussian distributions that are equal in number to the number of symbols of the symbol group becomes maximum.

The learning of the prediction device 203 in this embodiment has been previously completed. The learning process may be performed by this apparatus, or the learning may be performed by other apparatuses to enable this apparatus to use the index correspondence table 500 and the distribution table 600 that are the learning results. The prediction device 203 is configured so as to output one or more parameters of the probability density function that can be differentiated for the learning. In this embodiment, the prediction device 203 outputs two parameters of the Gaussian distribution as the probability density function, that is, the mean and the standard deviation as the two parameters.

The prediction device 203 outputs two parameters for each symbol in the feature amount map F. For example, when the number of symbols of the feature amount map F to be encoded by the range coder is 256*64*64=1048576, the prediction device 203 outputs 1048576*2=2097152 values. At the time of learning, individual Gaussian distributions in which 2097152+2=1048576 respectively using two parameters are configured from the 2097152 outputs. Then, the value of the coupling coefficient of the neural network that configures the prediction device 203 is repeatedly corrected so that the probability of each symbol value to be encoded is maximized, more strictly, the average value of all the symbols is maximized. On the other hand, at the time of compression, 2097152+2=1048576 indexes are created from the 2097152 outputs.

The index identification unit 221 refers to the index correspondence table 500, and identifies the index value corresponding to the combination of the two parameters that are the outputs of the prediction device 203. However, the prediction device 203 outputs the two parameters in a floating point number form, and when the parameters are used as-is, the number of combinations becomes enormous. Thus, the index identification unit 221 sections each parameter into a predetermined numerical value range, and calculates the representative value in the corresponding numerical value range. The range of this representative value is described as the minimum value and the maximum value in the setting table 650, and the width of each predetermined range is described as the granularity. In the example of the setting table 650 illustrated in FIG. 3, the predetermined numerical value ranges of the parameter A are, for example, the range of a width of 0.1 around −50, the range of a width of 0.1 around −49.9, the range of a width of 0.1 around −49.8, . . . , and the range of a width of 0.1 around 50.0.

However, in the predetermined numerical value range, the representative value is not necessarily required to be the center value, needs only to be decided on the basis of the previously defined rule, and may be the maximum value or the minimum value instead of the center value. For example, when the representative value is the minimum value, the predetermined numerical value ranges of the parameter A may be the range of −50 or more and less than −49.9, the range of −49.9 or more and less than −49.8, . . . , the range of 50.0 or more and less than 50.1. The index identification unit 221 identifies the numerical value range to which each parameter corresponds, determines the representative value in the numerical value range as the value of the parameter, and uses the value to identify the index value from the index correspondence table 500. For example, when for the representative values in the numerical value range, the parameter A is identified as “−50.0”, the parameter B is identified as “0.2”, and the index correspondence table 500 is the one illustrated in FIG. 4, the index value is identified as “1”.

Also, the index identification unit 221 assumes that when the parameter A and the parameter B outputted by the prediction device 203 are absent between the minimum value and the maximum value defined in the setting table 650, each of the parameter A and the parameter B is the value closer to any one of the minimum value and the maximum value by a clip process. For example, in the case where in the setting table 650, the minimum value of the parameter A is “−50” and the maximum value of the parameter A is “50”, when the parameter A outputted by the prediction device 203 is “−51”, the parameter A is handled as “−50”, and when the parameter A outputted by the prediction device 203 is “60”, the parameter A is handled as “50”.

The probability identification unit 222 uses the index value identified by the index identification unit 221, refers to the distribution table 600, and acquires the cumulative frequencies for all the symbols in the feature amount map. By using the acquired cumulative frequencies, the range coder of the entropy encoding unit 202 encodes the symbols to create the compression file 700 in which the amount of data is reduced. Precisely, the entropy encoding unit 202 creates a binary that is one portion of the compression file 700.

The compression file generation unit 230 creates a header that is another portion of the compression file 700. Specifically, the compression file generation unit 230 acquires the setting table 650 from the storage medium 114, and determines the setting table 650 as the header of the compression file 700 as-is.

Note that since in this embodiment, the range coder uses the cumulative frequency table to perform encoding, the distribution table 600 that represents the correspondence between the index and the cumulative frequency is used. However, the distribution table 600 may be a table that represents the relationship between the index and the appearance probability, and the cumulative frequency may be calculated for each relationship between the index and the appearance probability. When any one of the probability and the cumulative frequency can be acquired without calculating the probability density function, the higher speed effect of this embodiment can be obtained.

Compression File

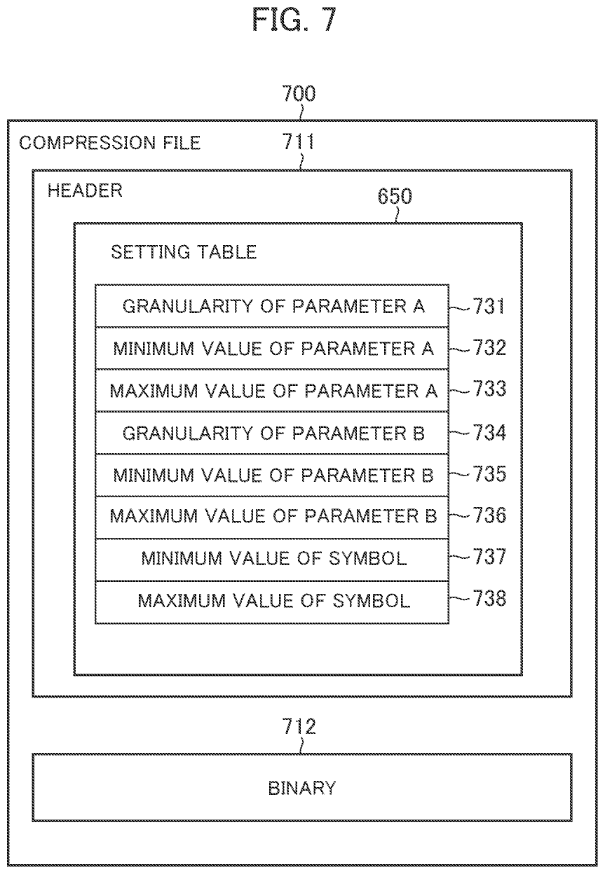

FIG. 7 is a diagram illustrating an example of the compression file 700 generated by the compression process. The compression file 700 includes a header 711 and a binary 712. The header 711 is created by the compression file generation unit 230, and the binary 712 is created by the entropy encoding unit 202. The header 711 is information that can regenerate the distribution table 600 used at the time of compression. For example, for the header 711, the information of the setting table 650 may be included as-is, or the same information as the setting table 650 may be stored in a different form. The binary 712 is a bit string outputted by the entropy encoding unit 202 described above. The reason why the compression file 700 has the information of the setting table 650 is as follows.

To use the binary 712 acquired by encoding in the compression process, it is necessary to perform the decompression process. In the decompression process, the binary 712 is decoded by a range decoder. In decoding by the range decoder, the same distribution table 600 as at the time of encoding is required for each symbol. Thus, the compression file 700 includes, as the header 711, the information that can regenerate the distribution table 600 used at the time of compression.

The setting table 650 has the information of a granularity 731 of the parameter A, a minimum value 732 of the parameter A, a maximum value 733 of the parameter A, a granularity 734 of the parameter B, a minimum value 735 of the parameter B, a maximum value 736 of the parameter B, a minimum value 737 of the symbol, and a maximum value 738 of the symbol. Note that the present invention is not limited to the examples of the parameter numbers. For example, the setting table 650 may hold an ID that can identify the same distribution table 600 as at the time of compression, and needs only to include information that enables any one of the regeneration of the same distribution table 600 as at the time of compression and the acquiring of the same distribution table 600 as at the time of compression from the storage medium, such as an HDD. Also, when the compression device uses only the single distribution table 600, the cumulative frequency information is not necessarily required to be included in the header of the compression file.

The compression device of this example acquires the information in the setting table 650 from the inside of the header 711 of the compression file 700 before the decompression process described later, and creates the same distribution table 600 as at the time of compression. Note that the present invention is not limited to this example, and when an ID that can identify the distribution table 600 is included in the compression file, the distribution table 600 may be regenerated on the basis of the ID, or may be acquired from the storage medium, such as an HDD, on the basis of the ID.

Decompression Process

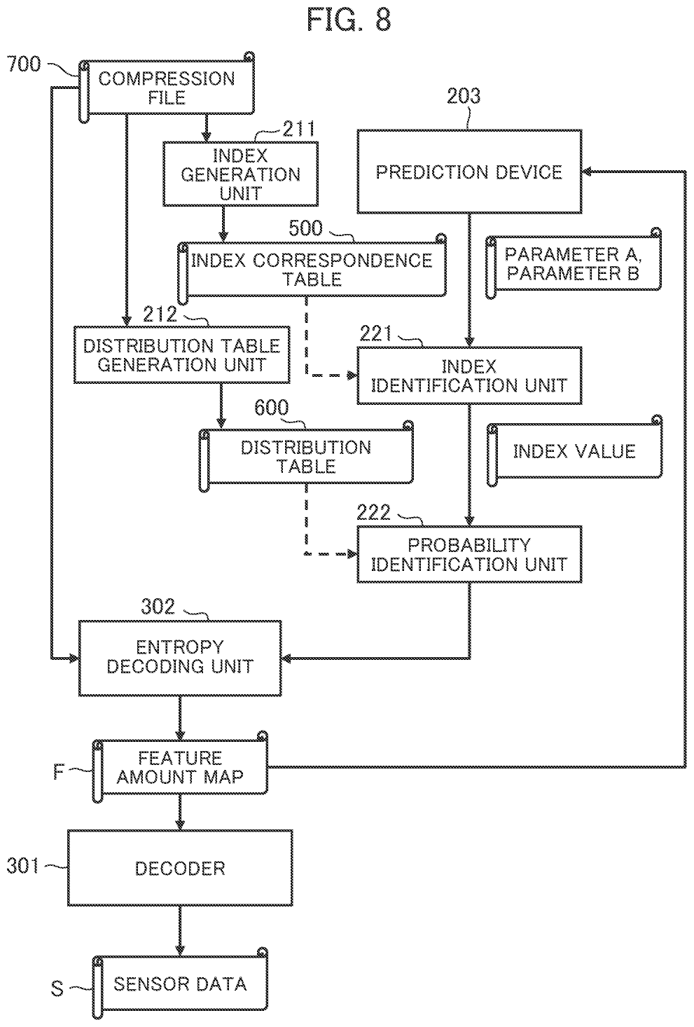

FIG. 8 is a flow diagram illustrating the decompression process. The decompression process of the computation apparatus 100 is started by a process for decoding the compression file 700 created by the compression process described above by the range decoder incorporated in the entropy decoding unit 302, and acquiring the feature amount map F.

The decoding process by the range decoder requires the same index correspondence table 500 and the same distribution table 600 as at the time of compression. Thus, the index generation unit 211 and the distribution table generation unit 212 refer to the header 711 of the compression file 700, and create the index correspondence table 500 and the distribution table 600, respectively. The feature amount map F that is the input of the prediction device 203 in the compression process is acquired as the result of decoding, so that the input of the prediction device 203 is not the same as the compression process in the decoding process.

The prediction device 203 inputs one portion of the feature amount map F, and predicts the appearance probability of the symbol of the one portion of the feature amount map F that is in a location different from the input. Thus, the feature amount map F is partly inputted, the appearance probability or the cumulative frequency distribution is acquired, and the one portion of the feature amount map F that is different from the input is decoded by the range coder. The one portion of the feature amount map F that is thus acquired is inputted to the prediction device 203 again, the appearance probability or the cumulative frequency distribution is acquired, and another portion of the feature amount map F that is different from the input is decoded by the range coder. In this way, the prediction-decoding loop process is repeated to finally acquire the whole of the feature amount map F. The first input for performing the prediction-decoding loop process may be stored in the compression file 700, or may be a dummy input.

In the prediction-decoding loop process in the decompression process, each time the prediction device 203 generates the parameter of the probability density function, the index identification unit 221 and the probability identification unit 222 operate as in the case of the compression process. By the prediction-decoding loop process, the whole of the feature amount maps F is decoded.

The decoded feature amount map F is converted to the original sensor data S by the decoder 301. The decoder 301 is configured to be paired with the encoder 201, compensates the value loss or the like caused by the encoder 201 by a process, such as smoothening, and operates so as not to cause a human to recognize uncomfortable feeling with respect to the image quality. The decoder 301 may be configured of the neural network, or may have any mechanism as long as the mechanism can convert the feature amount map F to the sensor data S. Note that the sensor data S to be subjected to the compression process and the sensor data S acquired by the decompression process are not necessarily required to be completely matched, and need only to be substantially the same. For example, the term “substantially the same” means that certainty that the sensor data S are the same in the perception of a human is a predetermined value or more, and that the result of the predetermined process is the same in the computer process.

User Interface

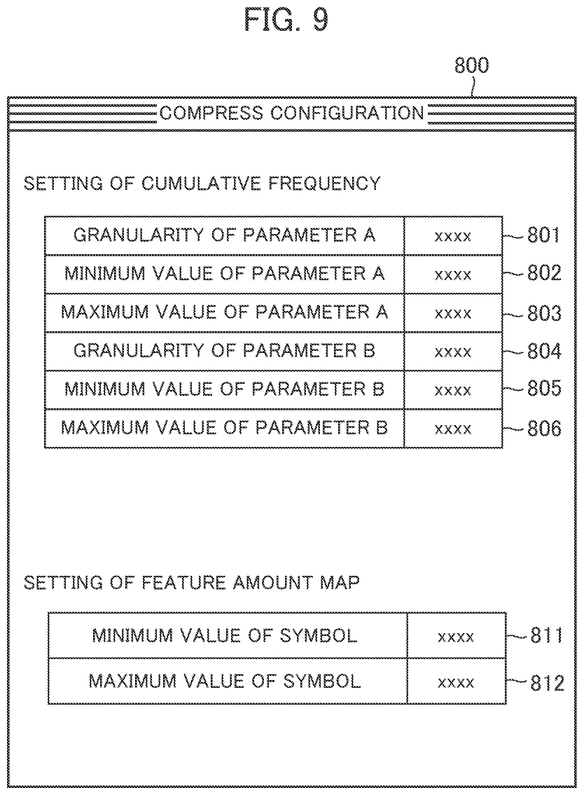

FIG. 9 is a diagram illustrating an example of a user interface screen 800 to which the user sets a set value. The user interface screen 800 is displayed on the computation apparatus 100 or the client terminal 103 connected to the computation apparatus 100 by the network 101.

The user interface screen 800 displays an example of a graphical user interface screen in order for the user to perform the setting.

The user interface screen 800 has, as the setting items of the cumulative frequency, input fields for a granularity 801 of the parameter A, a minimum value 802 of the parameter A, a maximum value 803 of the parameter A, a granularity 804 of the parameter B, a minimum value 805 of the parameter B, and a maximum value 806 of the parameter B. The user interface screen 800 has, as the setting items of the feature amount map F, input fields for a minimum value 811 of the symbol and a maximum value 812 of the symbol.

When there is an input from the user to the user interface screen 800, the computation apparatus 100 writes the input to the setting table 650, and reflects the input to the later process. Specifically, the distribution table generation unit 212 creates the distribution table 600 on the basis of the setting of the cumulative frequency. The setting of the feature amount map limits the symbol value outputted from the encoder 201. That's all for the user interface screen in this example.

Note that all of the setting items of the user interface screen 800 illustrated in FIG. 9 are not necessarily required to be included, and the user may be able to set only one item, or the user interface screen 800 is not necessarily required to be provided.

According to the first embodiment described above, the following operational advantages are acquired.

(1) The computation apparatus 100 has a prediction device, an encoder, and a decoder, and encodes and decodes data by using a probability density distribution. Of a learning process and a compression process, at least the compression process can be executed. By performing learning by using a neural network created by the learning process, a probability distribution table that causes a parameter and a symbol value probability distribution to correspond to each other can be used. In the compression process, the prediction device calculates the parameter from input data, and the encoder compresses the input data by using the symbol value probability distribution on the basis of the calculated parameter and the probability distribution table. Thus, the amount of computation can be reduced by previously performing the calculation of the probability density function that takes time for computation to create the distribution table 600, and by referring to the index correspondence table 500 and the distribution table 600 that have been previously created. The output of the neural network is typically a decimal fraction, and does not conform to the combination with a lookup table. In this embodiment, since the computation apparatus 100 has the index decision unit 240, the output of the neural network can be indexed, and can be used by being combined with the previously created lookup table. In other words, the processing time can be shortened, or the processing can be performed by more inexpensive processing resources, so that the cost of the computation process can be reduced.

(2) The computation apparatus 100 includes a probability identification unit that selects the symbol value probability distribution used for the compression on the basis of the calculated parameter and the probability distribution table.

(3) The parameter includes a mean and a distribution of the probability density distribution of the input data.

(4) The learning process is performed, and the learning process makes the coupling coefficient of the neural network more appropriate to create the probability density distribution.

(5) The learning process makes the coupling coefficient of the neural network more appropriate so that the distribution is made smaller.

(6) The learning process creates the probability density distribution for each group of plural symbols of the input data, calculates the parameters thereof, and sets the parameter stored in the probability distribution table at a predetermined granularity on the basis of a distribution range on the basis of the maximum value and the minimum value of the plural calculated parameters to describe the probability density distribution corresponding to the set parameter into the probability distribution table. Thus, the efficiency of compression can be improved without using the unnecessary parameter range.

Further, this embodiment also has the following operational advantages.

(7) The computation apparatus 100 includes the index decision unit 240 that sections the parameter of the probability density distribution outputted by the prediction device 203 into a predetermined numerical value range, and decides the index that is the value corresponding to the representative value in the corresponding numerical value range. The distribution table 600 represents the correspondence between the index and the value on the basis of the calculation result of the probability density distribution corresponding to the symbol. Thus, the correspondence between the output of the parameter and the cumulative frequency can be easily grasped.

(8) The index generation unit 211 that is one portion of the index decision unit 240 decides the granularity of the index, that is, the width of the predetermined numerical value range, on the basis of the instruction of the user. Thus, the trade-off between the accuracy of calculation and the creation time of the distribution table 600 previously created can be decided on the basis of the instruction of the user.

(9) The value on the basis of the calculation result of the probability density function in the distribution table 600 is the cumulative frequency distribution created on the basis of the calculation result of the probability density function. Thus, the cumulative frequency that takes longer time than the calculation of the probability is previously calculated, and the time required for the compression process can be shortened.

(10) The computation apparatus 100 includes the entropy encoding unit 202 that encodes, that is, compresses the feature amount map F that is input information, by using the value on the basis of the calculation result of the probability density function. Thus, the computation apparatus 100 can reduce the processing load of the compression process that creates the compression file 700.

(11) The computation apparatus 100 includes the compression file generation unit 230 that generates the compression file that combines the index parameter information that identifies each of the predetermined numerical value ranges described above, the probability identification information that identifies the correspondence information, and the input information outputted and encoded by the encoding unit. Thus, the computation apparatus 100 causes the compression file 700 to include the information in the setting table 650, so that the decompression process can be executed also in the different computation apparatus 100.

(12) The compression file 700 has a data structure including the index parameter information for sectioning, into the predetermined numerical value range, the parameter of the probability density distribution outputted by the prediction device 203 including the neural network that outputs the parameter of the probability density distribution according to the symbol inputted, the neural network being such that the coupling coefficient is changed so that the average value of the probabilities of the symbols of the Gaussian distribution created by using plural parameters corresponding to plural previously-inputted symbols is maximum, the probability identification information for sectioning the parameter outputted by the prediction device 203 into the predetermined numerical value range by using the index parameter information to acquire the value on the basis of the calculation result of the probability density distribution corresponding to the symbol by using the representative value in the corresponding numerical value range, and the binary 712 that is compressed data in which the symbol is compressed by using the value on the basis of the calculation result of the probability density distribution. Thus, the decompression process of the binary 712 can be efficiently executed by using the index parameter information and the probability identification information.

(13) The computation apparatus 100 includes the storage medium 114 that stores the compression file including the index parameter information for sectioning, into the predetermined numerical value range, the parameter of the probability density distribution outputted by the prediction device 203 including the neural network that outputs the parameter of the probability density distribution according to the symbol inputted, the neural network being such that the coupling coefficient is changed so that the average value of the probabilities of the symbols of the Gaussian distribution created by using plural parameters corresponding to plural previously-inputted symbols is maximum, the probability identification information for sectioning the parameter outputted by the prediction device 203 into the predetermined numerical value range by using the index parameter information to acquire the value on the basis of the calculation result of the probability density distribution corresponding to the symbol by using the representative value in the corresponding numerical value range, and the compressed data in which the symbol is compressed by using the value on the basis of the calculation result of the probability density distribution, the prediction device 203, the correspondence information creation unit that creates the correspondence information that represents the correspondence between the representative value and the value on the basis of the calculation result of the probability density distribution corresponding to the symbol on the basis of the probability identification information, that is, the index generation unit 211 and the distribution table generation unit 212, the probability identification unit 222 that identifies the value on the basis of the calculation result of the probability density distribution corresponding to the representative value by using the representative value acquired by sectioning the parameter of the probability density distribution outputted by the prediction device 203 into the predetermined numerical value range on the basis of the index parameter information and the correspondence information, and the entropy decoding unit 302 that decodes the binary 712 that is compressed data to the symbol by referring to the value on the basis of the calculation result of the probability density distribution. Thus, the computation apparatus 100 can decompress the binary 712 created on the basis of the value in any setting table 650 and stored in the compression file 700.

### Modification Example 1

The sensor server 102 may have the processing resources equivalent to the computation apparatus 100 to perform the compression process and the decompression process similar to those of the computation apparatus 100. Also, the computation apparatus 100 and the sensor server 102 may perform the compression process and the decompression process by the processing resources, such as a GPU or an FPGA, not by the processor.

### Modification Example 2

The number of parameters of the probability density function outputted by the prediction device 203 is not limited to two, and needs only to be one or more. The number of setting items of the setting table 650 increases or decreases according to the number of parameters outputted by the prediction device 203. And, the total number of indexes described in the index correspondence table 500 also changes according to the description in the setting table 650. According to this, the total number of indexes in the distribution table 600 also changes.

Also, when the probability density function having two or more parameters is used, one of the parameters may be a constant, and the prediction device 203 may output only one parameter. For example, the Gaussian distribution typically has a mean and a standard deviation as two parameters, but the mean may be a constant of 0, and the prediction device 203 may output only the standard deviation.

### Modification Example 3

The compression file 700 may include, instead of the setting table 650, information that identifies the index correspondence table 500 and the distribution table 600, for example, plural previously-created identifiers of the index correspondence table 500 and the distribution table 600. Further, the compression file 700 may include information that identifies the parameter of the prediction device 203 used in the compression process.

### Modification Example 4

In the first embodiment described above, one portion of the feature amount map F is inputted to the prediction device 203 at the time of decompression, but the prediction device that does not receive, as an input, the feature amount map Fat all at the time of decompression may be used. For example, in the compression process, a hyper feature amount map corresponding to the feature amount of the feature amount map F may be created from the feature amount map F by the prediction device 203, and the hyper feature amount map may be stored in the compression file separately from the binary 712 after the encoding of the feature amount map F by the range coder. With this configuration, the feature amount map is not required to be inputted to the prediction device at the time of decompression, and the prediction-decoding loop process described above is not required. At this time, when the amount of data of the hyper feature amount map is sufficiently made smaller, the data reduction effect by the entropy encoding of the feature amount map is fulfilled.

### Modification Example 5

In the first embodiment described above, the encoder 201 is not necessarily required to be used. In this case, instead of the feature amount map F, the sensor data S is inputted to the prediction device 203 and the entropy encoding unit 202.

### Modification Example 6

The output of the prediction device 203 is not limited to the parameter of the probability density function. The prediction device 203 needs only to output some numeral value as the output of the neural network. As long as the output of the prediction device 203 is the numeral value, the index correspondence table 500 corresponding to the numeral value range is previously created, so that the output of the prediction device 203 can be indexed by the index identification unit 221.

### Modification Example 7

In the first embodiment described above, the sensor data S has been described as the image mainly having two-dimensional expansion, but may be the output of a line sensor having a smaller number of dimensions than the image or the like, or a moving image having a larger number of dimensions than the image or the like. The number of dimensions of the feature amount map F changes according to the number of dimensions of the sensor data S, but the flow of the process is the same.

### Modification Example 8

In the first embodiment described above, the computation apparatus 100 executes both of the compression process and the decompression process. However, the computation apparatus 100 needs only to be able to execute at least one of the compression process and the decompression process. When the computation apparatus 100 executes only the compression process, the decoder 301 and the entropy decoding unit 302 need only to be removed from the configuration illustrated in FIG. 2. When the computation apparatus 100 executes only the decompression process, the encoder 201, the entropy encoding unit 202, and the compression file generation unit 230 need only to be removed from the configuration illustrated in FIG. 2.

### Modification Example 9

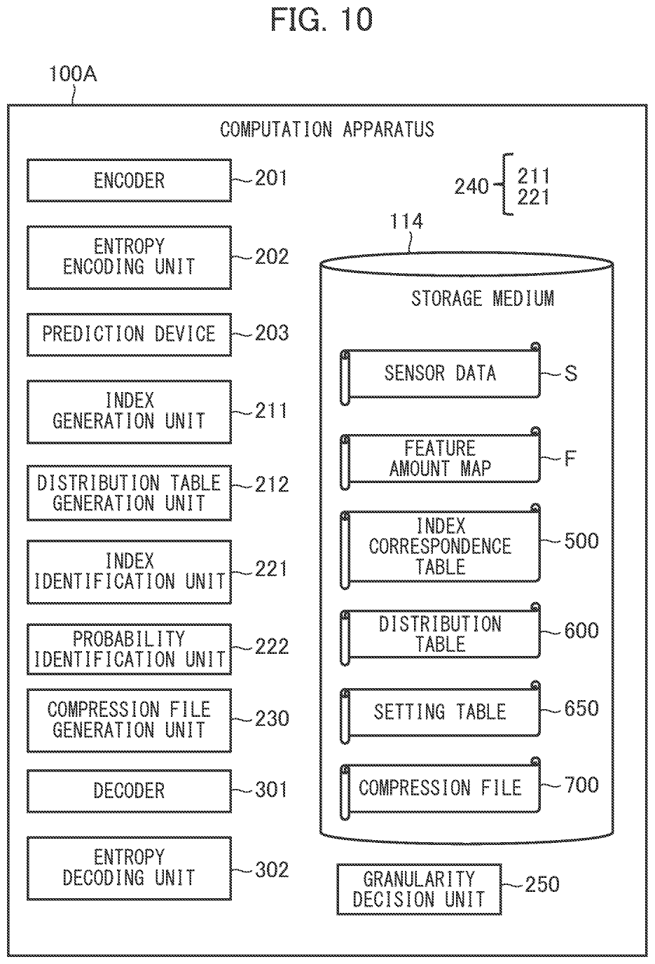

FIG. 10 is a function block diagram of a computation apparatus 100A according to modification example 9. The computation apparatus 100A illustrated in FIG. 10 further includes a granularity decision unit 250, in addition to the configuration according to the first embodiment. The granularity decision unit 250 decides the granularity of the parameter. That is, the granularity decision unit 250 decides at least one of the granularity of the parameter A and the granularity of the parameter B in the setting table 650.

For example, the granularity decision unit 250 executes benchmark for evaluating the computation capability of the computation apparatus 100A, and sets the granularity according to the score of the acquired benchmark. Also, the granularity decision unit 250 may acquire the information of the hardware configuration of the computation apparatus 100A from the operating system, the software platform, or the like of the computation apparatus 100A, and may estimate the computation capability from the hardware configuration to set the granularity. The granularity decision unit 250 sets the granularity so as to be finer as the score of the benchmark is higher, or as the estimated computation capability is higher.

According to this modification example, the computation apparatus 100A decides the granularity of the index decided by the index decision unit 240, that is, the width of the predetermined numeral value range described above, on the basis of the computation capability of the computation apparatus 100A. Thus, as the computation capability of the computation apparatus 100A is higher, the granularity of the index can be finer, so that the accuracy can be increased.

### Modification Example 10

In the distribution table 600, two parameters may be described instead of the index. That is, the distribution table 600 may be a table that represents the correspondence between the two parameters and the cumulative frequency. Note that each of the two parameters does not represent the parameter value itself, unlike the description in the index correspondence table 500, but is the representative value sectioned into the predetermined numeral value range.

### Second Embodiment

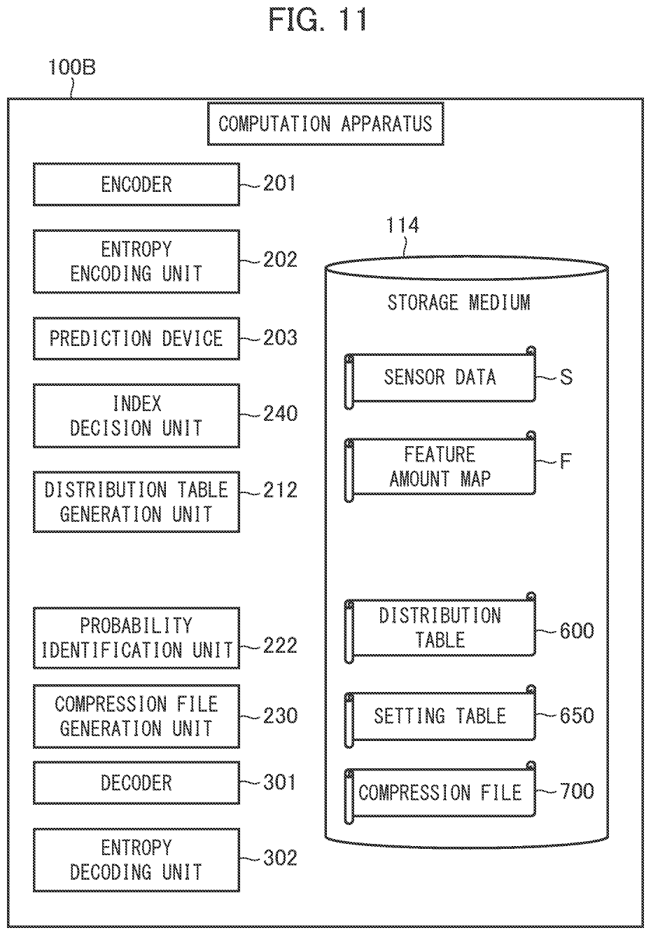

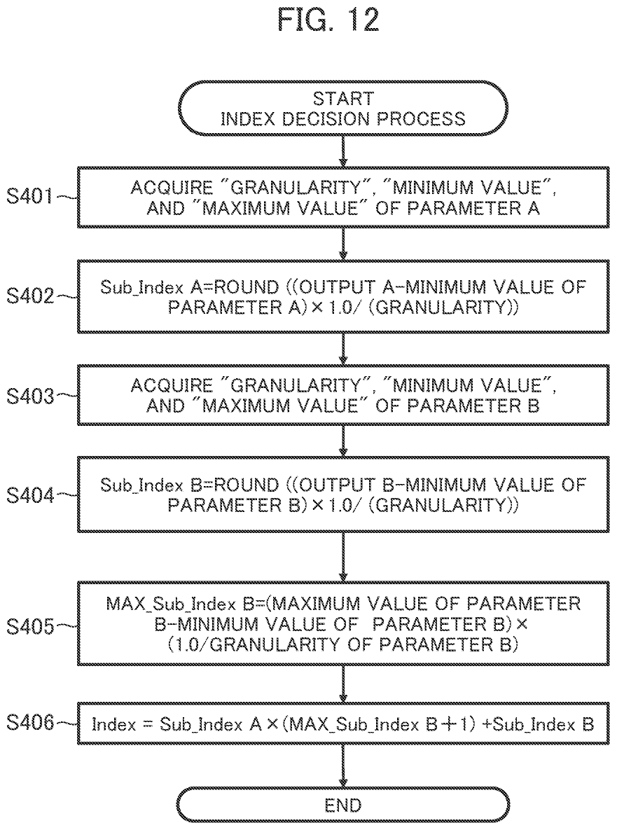

A second embodiment of a computation apparatus will be described with reference to FIGS. 11 and 12. In the following description, the same components as the first embodiment are indicated by the same reference numerals, and the different points will be mainly described. The points that are not particularly described are the same as the first embodiment. This embodiment is different form the first embodiment mainly in that the index correspondence table 500 is not necessarily required.

FIG. 11 is a function block diagram of a computation apparatus 100B according to the second embodiment. The index generation unit 211 and the index identification unit 221 are deleted from the configuration according to the first embodiment, and the index decision unit 240 serving as the functions of both is explicated. The index decision unit 240 identifies the index value without referring to the index correspondence table 500. That is, the index decision unit 240 performs mathematical equation computation in an index decision process described below by using the two parameters outputted by the prediction device 203 to identify the index value.

FIG. 12 is a flowchart illustrating the index decision process by the index decision unit 240. First, in step S401, the index decision unit 240 refers to the setting table 650 to acquire the “granularity”, “minimum value”, and “maximum value” of the parameter A. In subsequent step S402, the index decision unit 240 clips the parameter A by the minimum value and the maximum value to create an output A. Since the output value range of the neural network cannot be typically limited, the value outside the range of the parameter A in the previously created distribution table 600 can be outputted, so that the parameter A is required to be limited by clipping. By clipping, the value predicted by the prediction device 203 is changed, so that the prediction accuracy can be deteriorated, but when the value range of the parameter A in the distribution table 600 previously calculated is sufficiently large, the prediction accuracy deterioration can be ignored.

In order for the output A to be a positive integer value for indexing, the minimum value of the parameter A is subtracted from the output A. Then, the product of the resulting value and the reciprocal number of the granularity of the parameter A is taken, and is rounded off to be converted to an integer. The value that has been converted to the integer is called a sub-index A (Sub_Index A). In subsequent step S403, the “granularity”, “minimum value”, and “maximum value” of the parameter B are acquired from the setting table 650.

In subsequent step S404, the index decision unit 240 clips the parameter B that is the output of the prediction, by the minimum value and the maximum value to create an output B. Since the output of the neural network cannot be typically limited, the value outside the range of the parameter B in the previously created distribution table 600 can be outputted, so that the parameter B is required to be limited by clipping. By the clipping of the maximum value and the minimum value, the value predicted by the prediction device 203 is changed, so that the prediction accuracy can be deteriorated, but when the value range of the parameter B in the distribution table 600 previously calculated is sufficiently large, the prediction accuracy deterioration can be ignored.

In order for the output B to be a positive integer value for indexing, the minimum value of the parameter B is subtracted from the output B. Then, the product of the resulting value and the reciprocal number of the granularity of the parameter B is taken, and is rounded off to be converted to an integer. Hereinafter, the value that has been converted to the integer is called a sub-index B (Sub_Index B). In subsequent step S405, the maximum value of the sub-index B (MAX_Sub_Index B) is calculated as “(the maximum value of the parameter B−the minimum value of the parameter B)×(the reciprocal number of the granularity of the parameter B)”. In subsequent step S406, the computation of Index=Sub_Index A×(MAX_Sub Index B+1)+Sub_Index B is performed to calculate the index.

According to the second embodiment described above, the same operational advantage as the first embodiment is obtained without creating the index correspondence table 500.

In the respective embodiments and modification examples described above, the configurations of the function blocks are only an example. Some function configurations illustrated as separate function blocks may be integrally configured, or the configuration illustrated in one function block diagram may be divided into two or more functions. Also, one portion of the function that each function block has may be included in other function blocks.

In the respective embodiments and modification examples described above, the program that achieves the function that the computation apparatus 100 has is stored in the ROM, not illustrated, but the program may be stored in the storage medium 114. Also, the computation apparatus 100 may include the input/output interface, not illustrated, and the program may be read from other apparatuses via the input/output interface and the medium that can be used by the computation apparatus 100, as needed. Here, the medium refers to, for example, a storage medium that can be attached to or removed from the input/output interface, a communication medium, that is, a network, such as a wire network, a wireless network, or an optical network, or a carrier wave or a digital signal that propagates on the network. Also, part or all of the function achieved by the program may be achieved by a hardware circuit or an FPGA.

The respective embodiments and modification examples described above may be respectively combined. The various embodiments and modification examples have been described above, but the present invention is not limited to the contents of these. Other aspects that are considered in the scope of the technical idea of the present invention are also included in the scope of the present invention.

What is claimed is:

1. A computation apparatus that has a prediction device, an encoder, and a decoder and encodes and decodes data by using a probability density distribution,
wherein of a learning process and a compression process, at least the compression process can be executed,
wherein by performing learning by using a neural network created by the learning process, a probability distribution table that causes a parameter and a symbol value probability distribution to correspond to each other can be used, and
wherein in the compression process, the prediction device calculates the parameter from input data, and the encoder compresses the input data by using the symbol value probability distribution on the basis of the calculated parameter and the probability distribution table.

2. The computation apparatus according to claim 1, further comprising a probability identification unit that selects the symbol value probability distribution used for the compression on the basis of the calculated parameter and the probability distribution table.

3. The computation apparatus according to claim 1,
wherein the parameter includes a mean and a distribution of the probability density distribution of the input data.

4. The computation apparatus according to claim 3,
wherein the learning process is performed, and
wherein the learning process makes the coupling coefficient of the neural network more appropriate to create the probability density distribution.

5. The computation apparatus according to claim 4,
wherein the learning process makes the coupling coefficient of the neural network more appropriate so that the distribution is made smaller.

6. The computation apparatus according to claim 4,
wherein the learning process creates the probability density distribution for each group of plural symbols of the input data, calculates the parameters thereof, and sets the parameter stored in the probability distribution table at a predetermined granularity on the basis of a distribution range on the basis of the maximum value and the minimum value of the plural calculated parameters to describe the probability density distribution corresponding to the set parameter into the probability distribution table.

7. A compression method that is executed by a computation apparatus that has a prediction device, an encoder, and a decoder and encodes and decodes data by using a probability density distribution,
wherein the computation apparatus can execute, of a learning process and a compression process, at least the compression process,
wherein by performing learning by using a neural network created by the learning process, a probability distribution table that causes a parameter and a symbol value probability distribution to correspond to each other can be used, and
wherein the compression process includes:
calculating, by the prediction device, the parameter from input data; and
compressing, by the encoder, the input data by using the symbol value probability distribution on the basis of the calculated parameter and the probability distribution table.

8. A computation apparatus comprising:
a storage unit that stores a compression file including index parameter information for indexing the output of a neural network with respect to input information to an index value, probability identification information for acquiring an evaluation value by using the index value, and encoded data in which the input information is encoded by using the evaluation value;
a prediction device that includes the neural network and upon the input of one portion of the input information, outputs a numerical value corresponding to the one portion of the input information;
an index decision unit that decides an index on the basis of the numerical value outputted by the prediction device on the basis of the index parameter information;
a correspondence information creation unit that creates correspondence information that represents the correspondence between the index and the evaluation value on the basis of the probability identification information;
an identification unit that identifies the evaluation value corresponding to the index by referring to correspondence information; and
a decoding unit that decodes the encoded data to the input information by referring to the evaluation value.
